(19) United States
(12) Patent Application Publication
(10) Pub. No.: US 2020/0198687 A1
(43) Pub. Date: Jun. 25, 2020

(54) ELECTRONIC CONTROL UNIT FOR A POWER STEERING UNIT

(71) Applicants: THYSSENKRUPP PRESTA AG, Eschen (LI); thyssenkrupp AG, Essen (DE)

(72) Inventors: Philippe STECK, Eschen (LI); Francisco ASENSIO, Arbon (CH); Katrin BLANK, Satteins (AT)

(73) Assignees: THYSSENKRUPP PRESTA AG, Eschen (LI); thyssenkrupp AG, Essen (DE)

(21) Appl. No.: 16/615,011

(22) PCT Filed: May 25, 2018
(86) PCT No.: PCT/EP2018/063808

§ 371 Date: Nov. 19, 2019

(30) Foreign Application Priority Data
May 30, 2017 (DE) 10 2017 111 796.2

(51) Int. Cl. B62D 5/04; H02K 11/33; H02K 5/10; H02K 5/22; H05K 5/00

(52) U.S. Cl. CPC B62D 5/0406; H02K 11/33; H05K 5/0065; H02K 5/225; H02K 5/10

(57) ABSTRACT

An electronic control unit for a power steering unit includes a multi-part housing. An electronic circuit is enclosed in the housing and is arranged in an interior space thereof. At least one plug contact includes a number of electrical contact elements which extend through the housing, includes contact surfaces arranged outside the interior space and reach into the interior space, where they are connected to the electronic circuit. The interior space is partially or completely filled with a closed-cell foam which is an elastic foam with an elongation at break of at least 20%.

The present invention relates to an electronic control unit with the features of the preamble of claim 1.

In motor vehicles, power assisted steering or servo steering systems are increasingly being provided with an electromotively driven power steering unit. This unit may be provided at various locations of the steering system, to be specific on the steering column, on the steering pinion or on the steering rack. In all cases, it is advantageous to integrate the electronic control unit, which directly activates the electric motor, in an assembly with the electric motor. Since this assembly is arranged in the region of the axle or in the engine compartment, special requirements regarding the seal-tightness of the control unit must be observed. In particular, it should be prevented that particles or water can penetrate into the control unit.

It is known from the document DE 102013104358 A1 to seal the electronic control unit by a cover. The control unit is in this case located in a separate housing, which can be sealed by a baseplate interacting with the housing in a dustproof manner. However, it is found in practice that even this design of housing is not sufficiently seal-tight in all cases.

On this basis, the object of the present invention is to design an electronic control unit in such a way that the operational reliability is not impaired even when it is externally exposed to water and particles. It should also be prevented that particles that are already in the control unit impair the function of the electronic control.

This object is achieved by an electronic control unit with the features of claim 1 or 2.

Because in the case of an electronic control unit for a power steering unit with a multi-part housing, which encloses an electronic circuit arranged in an interior space of the housing, and with at least one plug contact, which comprises a number of electrical conductors which extend through the housing, comprise contact surfaces arranged outside the interior space and reach into the interior space, where they are connected to the electronic circuit, the interior space is partially or completely filled with a closed-cell foam, which is an elastic foam with an elongation at break of more than 5%, preferably with an elongation at break of at least 10%, more preferably of at least 20%, the foam, and as a result also the electronic components of the control unit individually and the control unit as a whole, are not damaged even when exposed to mechanical stress due to vibrations or temperature changes. In particular, enclosed particles remain securely fixed in the foam, so that metallic particles cannot cause a short circuit and no particles emerge from the foam material because of ruptures of the foam structure. It is preferred that the elongation at break of the foam is at least 40%. The elongation at break in this case indicates by how many percent the foam can be stretched before it ruptures. Particularly preferably, a single-component foam is suitable here as the elastic foam. However, it is also conceivable and possible to use a two-component foam. If the foam contains bubbles with a diameter of on average less than 1 mm, preferably less than 0.1 mm, a particularly advantageous binding capability for enclosed particles is obtained, and additionally a particularly good sealing effect against particles penetrating from outside. Particularly preferably, the unexpanded foam material has a low density of less than 1000 kg/m³, in particular less than 750 kg/m³, so that the foam has a low weight or, to put it another way, is lightweight. In the expanded state, on contact with air, the weight of the foam is reduced, the density of the foam preferably being less than 40 kg/m³, preferably less than 10 kg/m³. As a result, the use of the foam has only a slight effect on the weight of the control unit.

In this case, the foam preferably comprises between 1000 and 100 000 bubbles per cm³, resulting in an advantageous ratio of the sealing function and the binding function and weight.

In the case of a preferred embodiment, the foam, with an average bubble size of less than 0.1 mm, comprises between 100 000 and 800 000 bubbles per cm³, in particular between 400 000 and 800 000 bubbles per cm³. Such a fine-cell foam can ensure particularly good heat conduction.

Crack formation or crack propagation within the foam can be prevented even under great stresses if the foam is a synthetic resin foam with embedded particles of a rubber-elastic material, for example of ethylene-propylene-diene (monomer) rubber (EPDM) or acrylonitrile-butadiene rubber, also nitrile rubber for short (abbreviations AB and NBR). In the case of foams of such a configuration, incipient cracks in the material end as soon as they reach such an embedded particle.

Preferably, the foam is not completely crosslinked and, if there is crack formation, is self-repairing. Self-repairing means in this case that the foam is formed as a not completely crosslinked foam. This design has the advantage during operation that cracks or other structural damage possibly occurring in the foam can be automatically cured by crosslinking then continuing, even in the long term over the entire intended operating life of the control unit.

The thermal conductivity is improved if the foam contains graphite particles as a filler. It is in this case preferred if the foam contains between 3% by weight and 20% by weight, in particular 4% by weight, of graphite particles. Local heating of embedded components is thereby avoided.

The heat capacity is improved if the foam contains paraffin as a filler. It is in this case preferred if the foam contains between 3% by weight and 20% by weight, in particular 5% by weight, of paraffin. As a result, the foam can compensate for temperature peaks occurring in the short term at embedded electronic components.

Finally, it may be of advantage if the foam is electrically conductive. If such a foam is arranged in a component of the unit in which a plug contact is located, contact formation can be supported by the foam.

Because an electronic control unit for a power steering unit with a multi-part housing, which encloses an electronic circuit arranged in an interior space of the housing, and with at least one plug contact, which comprises a number of electrical contact elements which extend through the housing, comprise contact surfaces arranged outside the interior space and reach into the interior space, where they are connected to the electronic circuit, a first housing part being connected to a second housing part by way of a closed-cell foam, whereby an undetachable connection of the housing parts is formed, the foam acts as an adhesive between the housing parts, so that the housing parts can thereby be held, directed and closed. This has the advantage that there is no need for a screw connection between the housing parts, obviating the need for components and processing steps on the housing parts. For this purpose, at least one of the housing parts may comprise at least one filling opening for filling with the foam.

Exemplary embodiments of the present invention are described in more detail below on the basis of the drawing. Components that are the same or functionally the same are in this case provided with the same reference numerals. In the drawing:

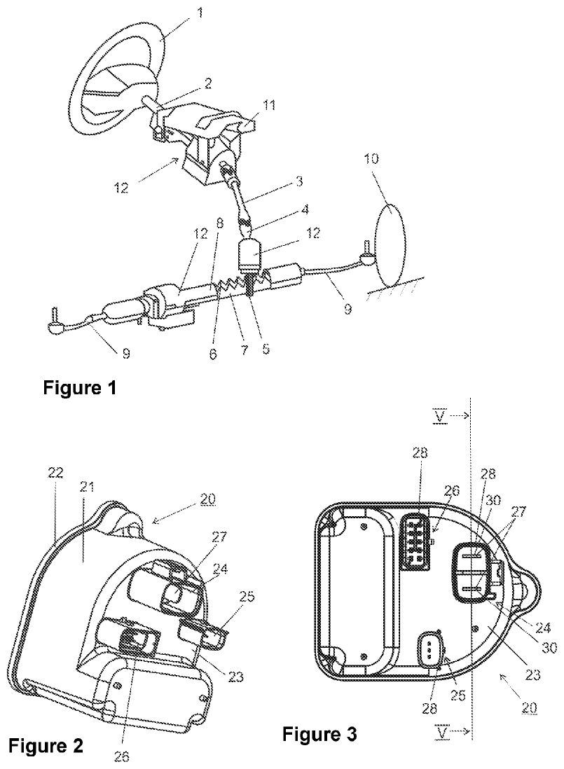

FIG. 1: shows a schematic representation of a motor vehicle steering system with electrical power steering;

FIG. 2: shows an electronic control unit for electrical power steering in a perspective representation;

FIG. 3: shows the control unit from FIG. 2 in a plan view of the connection side;

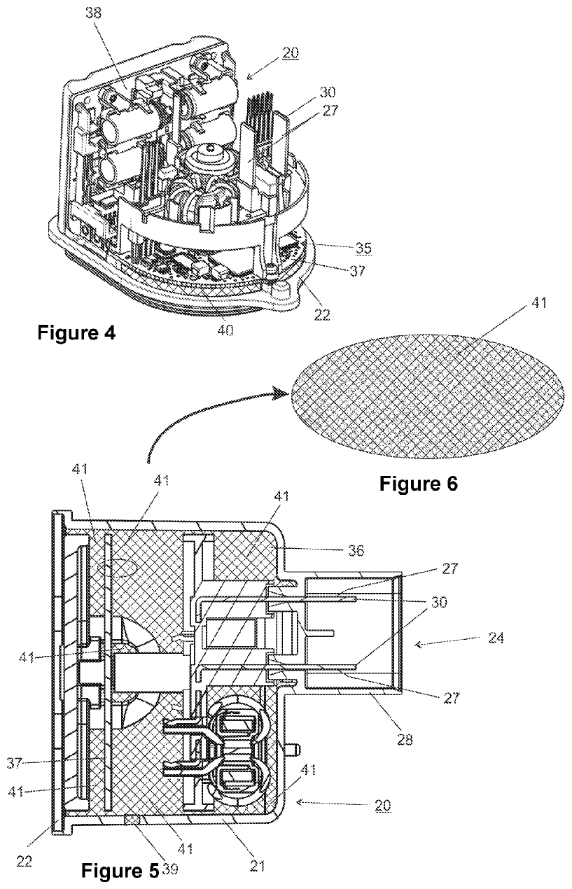

FIG. 4: shows the control unit from FIGS. 2 and 3 in a perspective representation with the housing cover removed;

FIG. 5: shows the control unit in a longitudinal section along the line V-V from FIG. 3;

FIG. 6: shows a schematic representation of the foam structure from the indicated region of the interior space of FIG. 5;

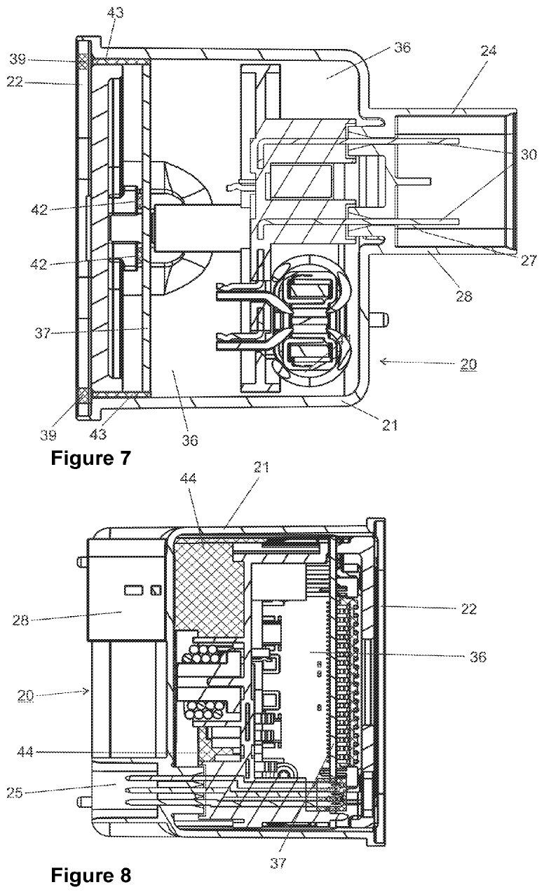

FIG. 7: shows a control unit in the representation according to FIG. 5 with only partially foam-filled regions; and

FIG. 8: shows a control unit in another sectional representation, likewise with partially foam-filled regions.

FIG. 1 shows an electromechanical servo steering system in a representation of the principles involved. The servo steering system comprises in a known way a steering wheel 1, which is coupled for conjoint rotation with an upper steering shaft 2, a lower steering shaft 3 and a pinion shaft 4. The pinion shaft 4 bears at its end remote from the steering wheel 1 a pinion 5, which is in engagement with a toothing 6 of a steering rack 7. The steering rack 7 is in turn displaceably mounted in a steering housing 8 and respectively bears at its ends a tie rod 9. The tie rods 9 are connected in a known way to steering knuckles (not shown) of a steerable axle, so that a turning of the steering wheel 1 leads to a displacement of the steering rack 7, and consequently to a pivoting of steerable wheels 10 during operation. FIG. 1 is intended to be understood only as a representation of the principles involved, because altogether three possible arrangements of a servo drive are shown here. A first possible arrangement is located in the region of the upper steering shaft 2 on a steering column 11. A power steering unit 12 arranged there drives the steering shaft 2 directly. This arrangement is known as “column drive”. A second possible arrangement of the power steering unit 12 is located on the pinion shaft 4. The servo drive in this case drives the pinion 5 directly. This arrangement is known as “pinion drive”. Finally, a power steering unit 12 may also be arranged in the steering housing 8 and act on the steering rack 7 directly. This embodiment is known as “rack drive”. The present invention can be used equally for all three variants mentioned of an electromechanical steering system.

Provided as the drive in the case of all three variants is an electric motor, which is usually designed as a brushless, electronically commutated motor. This motor is activated directly by an electronic control, which is integrated in a control unit. The control unit in this case comprises a multiplicity of electronic components, which are required for the conversion of control pulses into activation signals for the electric motor, and in particular also components of the power electronics that provide the power supply for the motor. In the case of electromechanical motor-vehicle steering systems, the control unit is usually provided with a housing of its own and is arranged directly on the housing of the electric motor. In the case of the two last-mentioned types of construction of an electromechanical servo steering system, the housing of the control unit is located in the engine compartment or directly on the axle of the vehicle, and therefore in a region that is exposed to temperature fluctuations, wetness and dirt.

FIG. 2 shows an electronic control unit 20 of a power steering unit 12 in a perspective representation. The control unit 20 comprises a second housing part 22, which from now on is referred to as housing 22, which is closed on one side by a first housing part 21, which from now on is referred to as housing cover 21. Arranged on a rear side 23 of the control unit 20 are plug connections 24, 25 and 26. The plug connections 24, 25 and 26 serve for connecting the control unit 20 to a cable harness (not shown) of the torque sensor. The plug connections 24, 25 and 26 comprise in a known way metallic contact elements with a metallic contact surface 27 that is externally accessible and not provided with an insulation coating. In FIG. 2, only the contact surface 27 of the plug connection 24 is denoted by a reference numeral, since it can be seen best. The contact surface 27 of the plug connection 24 is formed with a very large surface area in comparison with the contact surfaces of the plug connections 25 and 26, because the plug connection 24 is intended for the general power supply to the electric motor, which requires high current intensities.

FIG. 3 shows the control unit 20 from FIG. 2 in a plan view of the connection side. The plug connection 24 comprises an outer casing 28, which mechanically guides the matching plug of the cable harness and is locked in the end position. A contact element 30, which bears the contact surface 27, is configured in a way known per se as a strip-shaped, metallic contact element and is oriented in its longitudinal extent perpendicularly to the plane of the rear side 23. The contact element 30 in this case passes through the wall of the housing cover 21 and is connected in the interior of the control unit 20 to an electronic circuit. The same applies correspondingly to the other contact elements in the plug connections 25 and 26. These, too, are made of metal and configured as strip-shaped or pin-shaped contacts, which reach from the exterior space into the interior space of the control unit 20.

The control unit 20 is shown in FIG. 4 perspectively with the housing cover removed. The contact elements, in particular the contacts 30 of the plug connection 24, are fastened on an electronic circuit 35, which is located in an interior space 36 enclosed by the housing cover 21. The electronic circuit 35 comprises a first circuit board 37, on which control components with a relatively low power demand are located. A further circuit board 38 is oriented approximately at right angles to the circuit board 37 and especially carries components of the power electronics, which serve for the direct activation of the electric motor and produce considerable amounts of heat during operation. Between the circuit board 37 and the underside of the housing 22, in this exemplary embodiment the interior space is filled with a foam 40. The foam 40 in this case fills the entire space between the circuit board and the housing 22. It may in this case serve for example for fixing particles of plastic or else metal occurring there because of the production process, and thus hinder them from moving about in an uncontrolled manner in the remaining interior space 36.

FIG. 5 shows the control unit 20 from FIG. 3 in a longitudinal section along the line V-V. In this exemplary embodiment, the housing cover 21 has been placed onto the housing 22. The construction of the plug connection 24 with the casing 28 and the contact elements 30 can be clearly seen in section in this representation. A foam 41 is arranged in the entire interior space 36, so that it lies in full-area contact against the housing 22 and against the housing cover 21, and in particular completely encloses the circuit board 37. This complete foam-filling of the interior space 36 also brings about the effect in particular that the contact elements 30, which extend through the housing cover 21, are surrounded by the foam 41 where they are exposed in the interior space 36. This measure is advantageous because, as represented in FIG. 4, the contact elements 30 are fastened on the electronic circuit, and the cover 21 has openings which allow the contact elements 30 to pass through the housing cover 21 when the housing cover 21 is placed onto the housing 22. It is not always ensured thereby that the contact elements 30 completely seal the corresponding through-opening of the housing cover 21. During assembly, a plug is indeed placed onto the plug connection 24, which then brings about a sealing effect with the casing 28. However, particles that are possibly present in the interior space of the plug connection 24 could in an unfavorable case pass between the housing cover 21 and the contact element 30 into the interior space 36 of the control unit 20. Complete filling with foam 41, as shown in FIG. 5, in this case prevents the penetration of particles. The foam-filling of the interior space 36 takes place in this case after the placing of the housing cover 21 onto the housing 22. The housing cover 21 has a filling opening 39, into which the foam 41 can be injected. The filling opening 39 may also be provided on the housing 22. The filling with the foam 41 takes place after the housing cover 21 has been fitted onto the housing 22. As a result, enclosed particles are securely fixed in the foam, and at the same time the housing parts 21, 22 are firmly connected to one another. This obviates the need for fixing means between the housing parts 21, such as for example connecting screws. Furthermore, the injection of the foam 41 through the filling opening 39 makes it possible that a number of components within the housing parts 21, 22, such as for example the circuit board 37, 38 and the elements arranged on it, are undetachably fixed to one another.

The structure of the foam 41 is intended to be illustrated by way of example in FIG. 6. The foam 41 is a closed-cell foam, in particular a single-component or two-component synthetic resin foam with an elongation at break of 20% or more. The synthetic resin foam comprises a large number of internal bubbles, which have a small diameter of preferably below 1 mm. More details of the properties of the foam that is used have been set out further above in the description. On account of the elongation at break of 20% or more, the foam will not break during operation even when there are unavoidable mechanical stresses as a result of shocks, vibrations and temperature differences. Enclosed particles are therefore securely fixed and not released again. The foam itself likewise does not release any particles, in the way that may occur over time at the rupture points in the case of rigid, inelastic foams with lower elongation at break.

In FIG. 7, a section is shown in a way corresponding to FIG. 5. In the case of this exemplary embodiment, the interior space 36 is substantially not foam-filled. Here, a foam 42 is only provided on the underside of the circuit board 37, to be precise also only in the middle region shown, which comprises non-coated conductor tracks. The conductor tracks are covered by the foam 42, so that the risk of short-circuits or other disturbances due to foreign metallic particles is specifically dispelled in this region. A further foam 43 is respectively provided at the outer circumference of the housing cover 21, in the region between the circuit board 37 and the housing 22. The foam 43 is adhesively connected to the housing cover 21 and the housing 22 and also to the outer periphery of the circuit board 37, and consequently seals the interior space 36 in the region of the joint between the housing cover 21 and the housing 22 with respect to the region lying behind it of the housing 22 or the interior space 36. This exemplary embodiment is intended to illustrate that foams according to the invention can be selectively used for sealing or covering, and do not necessarily have to fill the entire interior space 36. It may alternatively or additionally be envisaged to provide foams such as the foam 42 or the foam 43 also at other points of the control unit 20. It is also shown in FIG. 7 that the housing cover 21 can be partially adhesively bonded to the housing 22. For this purpose, the housing 22 has filling openings 39, into which the foam 43 can be injected. In FIG. 8, finally, the control unit 20 is shown in section in another view. In the case of this exemplary embodiment, a foam 44 is specifically arranged in a region of the interior space 36 that is directly adjacent to the plug connector 28. The foam 44 may in this case reach into the region that lies behind the sectional plane in FIG. 8. This region contains the circuit board 37 with the components of the power electronics. In this exemplary embodiment, the foam 44 may be filled with graphite particles, paraffin or both as a filler. Graphite increases the thermal conductivity of the foam 44. Paraffin increases the heat capacity of the foam 44. An increased thermal conductivity serves the purpose of dissipating the heat of the power electronics that is produced during operation. For an improved thermal conductivity, the foam may be transparent in a certain wavelength range, for example in the infrared range. An increased heat capacity of the foam 44 serves the purpose of absorbing the amount of heat occurring in the short term when there are power peaks, and as a result of additionally cooling the power electronics and protecting them from damage.

In all of the exemplary embodiments, the foams 40-44 may be formed as not completely crosslinked foams. This design has the advantage during operation that cracks or other structural damage possibly occurring in the foam can be automatically cured by crosslinking then continuing, even in the long term over the entire intended operating life of the control unit 20. It is also conceivable and possible to use the foam in the form of foam sheet. The foam sheet is waterproof, temperature-permeable and elastic.

1.-12. (canceled)

13. An electronic control unit for a power steering unit, comprising:
a multi-part housing;
an electronic circuit enclosed within an interior space of the housing;
a plug contact comprising:
a number of electrical contact elements that extend through the housing, and
contact surfaces arranged outside the interior space and reaching into the interior space and connected to the electronic circuit, and
closed-cell foam partially or completely filling the interior space, wherein the foam is an elastic foam with an elongation at break of more than 5%.

14. The control unit of claim 13 wherein the elongation at break of the foam is at least 10%.

15. The control unit of claim 13 wherein the foam contains bubbles with an average diameter of 1 mm.

16. The control unit of claim 13 wherein the foam contains bubbles with an average diameter less than 0.1 mm.

17. The control unit of claim 13 wherein the foam comprises between 1,000 and 100,000 bubbles per cm³.

18. The control unit of claim 13 wherein the foam contains bubbles having an average diameter of less than 0.1 mm and comprises between 100,000 and 800,000 bubbles per cm³.

19. The control unit of claim 13 wherein the foam is a synthetic resin foam with embedded particles of a rubber-elastic material.

20. The control unit of claim 13 wherein the foam is not completely crosslinked and is self-repairing of cracks.

21. The control unit of claim 13 wherein the foam contains graphite particles as a filler.

22. The control unit of claim 21 wherein the foam contains between 3% by weight and 20% by weight of graphite particles.

23. The control unit of claim 13 wherein the foam contains paraffin as a filler.

24. The control unit of claim 23 wherein the foam contains between 3% by weight and 20% by weight of paraffin.

25. An electronic control unit for a power steering unit, comprising:
a multi-part housing, comprising:
a first housing part, and
a second housing part non-detachably connected to the first housing part by way of a closed-cell foam;
an electronic circuit enclosed within an interior space of the housing; and
a plug contact, comprising:
a number of electrical contact elements that extend through the housing, and
contact surfaces arranged outside the interior space and reaching into the interior space and connected to the electronic circuit.

26. The control unit of claim 25 wherein the elongation at break of the foam is at least 10%.

27. The control unit of claim 25 wherein the foam contains bubbles with an average diameter less than 0.1 mm.

28. The control unit of claim 25 wherein the foam comprises between 1,000 and 100,000 bubbles per cm³.

29. The control unit of claim 25 wherein the foam is a synthetic resin foam with embedded particles of a rubber-elastic material.

30. The control unit of claim 25 wherein the foam is not completely crosslinked and is self-repairing of cracks.

31. The control unit of claim 25 wherein the foam contains graphite particles as a filler.

32. The control unit of claim 25 wherein the foam contains paraffin as a filler.
